(19) United States
(12) Patent Application Publication
(10) Pub. No.: US 2012/0187257 A1
(43) Pub. Date: Jul. 26, 2012

(54) Tablet PC Stand

(76) Inventor: JIANHUA ZOU, Guangzhou City (CN)

(21) Appl. No.: 13/013,777

(22) Filed: Jan. 25, 2011

(51) Int. Cl. H05K 7/14

(52) U.S. Cl. 248/125.8

(57) ABSTRACT

A computer accessory for provides a fixing stand for tablet PC or other e-book products such as “ipad®” comprising: a base; a height rod, which is vertical to the base; a metal hose, at which one end of the hose is fixed to the top end of the height rod; and a fixing holder, connecting to the other end of the metal hoses for clamping tablet PC or e-book. For user's convenience, the tablet PC stand can be moved with the whole body. Users can bend the metal hoses as like. The fixing holder can be rotated at 360 degrees to adjust tablet PC or e-book's best place in height, horizontal and angle and make users in the best comfortable gestures.

### FIELD OF THE INVENTION

This invention relates to a computer accessory, more specifically provides a fixing support to fix tablet personal computer (PC) or other e-book products such as “ipad®”.

### BACKGROUND OF THE INVENTION

As the rapid progress in computer data transmission and storage capacity, there are many innovation for tablet PC or e-book, such as personal digital assistants (PDA) and some other equipments, which are well received by the market.

In particular, Apple Company launched “iphone®”, “ipad®” series products, and quickly be warmly welcomed by consumers. More and more people use the e-book or other products similar with e-book.

When using them, most people are used to hand-holding e-book, or put the e-book on the table, and then eyes and body ingratiate themselves to screen. This usage method is prone to make people feeling tired, and will be subject to certain restrictions. To facilitate reading, fixation support can be used to adjust and fix e-book.

Known fixations usually carry the e-book with a plate body, articulated to a relative open and recovered tripod in the back of the plate. Fixations are still inconvenient to adjust the height and angle of tablet PC or e-book, and also not adapt to the existing diversity of tablet PC or e-book's models, sizes.

### SUMMARY OF THE INVENTION

For existing problem in technology, this invention, has the purpose to provide a tablet PC or e-book stand, which can be move to anywhere as users like, and can be adjusted to the height and angle arbitrarily.

To achieve the goals above, the tablet PC stand of present invention comprising: a base; a height rod, which is vertical to the base; a metal hose, one end fixes to the top of height rod; a fixing holder, connecting to the other end of the metal hoses to clamp the tablet PC or e-book. The fixing holder contains at least three flexible grippers to fix the tablet PC or e-book with different shapes and sizes.

Present invention of the tablet PC stand can be moved with the whole body in convenience. Users can bend the metal hoses as like. The fixed holder can be rotated at 360 degrees to adjust the best place in height, horizontal and angle and to offer users the best comfortable gestures. The fixed holder contains at least three flexible grippers to fix the tablet PC or e-book with different shapes and sizes.

Present invention of the tablet PC stand can be moved in whole to anywhere as users want. After set and fixed the tablet PC or e-book at the fixed holder, users can bent the metal hoses and rotate the fixed holder to make the tablet PC or e-book in any height and angle, which make users can enjoy tablet PC or e-book in bedroom, living room, and even in balcony, no matter you are lying, sleeping, sitting or standing. It changes the previous way of using tablet PC or e-book like hand-held or put on table, also avoids eyes and body ingratiating to the screen. The main characteristics of the invented tablet PC support above are that it not only can be used directly, convenient and flexible on the floor, but also use small space, simple operation, little limited of places and durable.

### BRIEF DESCRIPTION OF THE DRAWING

FIG. 1 shows the structure diagram of the present invention.

### DETAILED DESCRIPTION OF THE INVENTION

Combining with drawing, the followings are further illustration of the tablet PC stand.

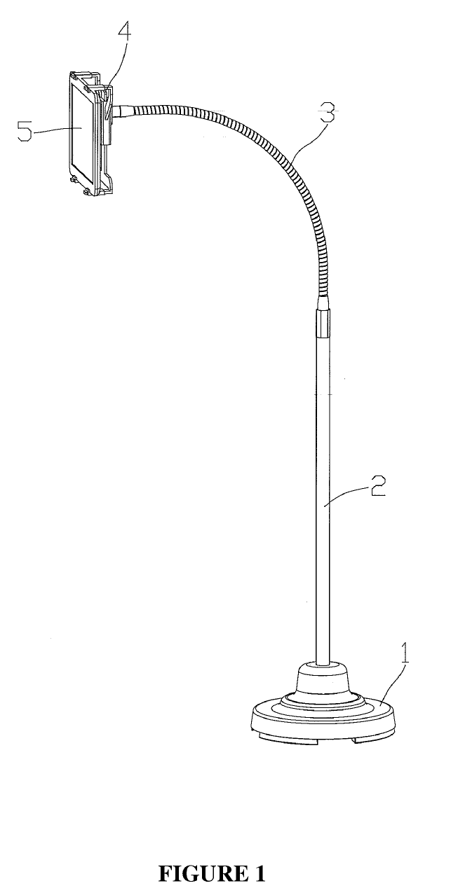

As shown in the FIG. 1, the tablet PC stand comprising: a base 1; a height rod 2, which is vertical to the base; a metal hose 3, one end fixes to the top of height rod 2; a fixing holder 4, connecting to the other end of the metal hose 3 to clamp the tablet PC or e-book 5. The above-mentioned fixing holder 4 contains at least three flexible grippers to fix the tablet PC or e-book 5 with different shapes and sizes. When adjusting only need bend the metal hose and rotate the fixing holder to make the tablet PC or e-book 5 in the best angel, height and distance. Using this invented tablet PC or e-book stand, users can not only relieve hands from laborious holding the tablet PC or e-book, but also liberate users' hands to operate the tablet PC or e-book more flexible and even drink water, call someone or do other things at the same time.

1. A tablet PC stand comprising: a base; a height rod, which is vertical to the base; a metal hose, one end fixes to the top of height rod; a fixing holder, connecting to the other end of the metal hoses to clamp the tablet PC, e-book or “ipad”.

2. The tablet PC stand as claimed in claims 1 wherein, it is characteristic is the height rod is vertical to the base.

3. The tablet PC stand as claimed in claims 1 above about the tablet PC support, its characteristic is the fixing holder is fixed at the metal hose which can be bent as like.

4. The tablet PC stand as claimed in claims 1, its characteristic is the fixed holder contains at least three flexible grippers to fix the tablet PC or e-book with different shapes and sizes.
